(19) United States
(12) Patent Application Publication
(10) Pub. No.: US 2025/0140746 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Feng KAO, Taichung City (TW); Lung-Yuan WANG, Taichung City (TW)

(21) Appl. No.: 18/654,916

(22) Filed: May 3, 2024

(30) Foreign Application Priority Data
Oct. 27, 2023 (TW) 112141376

(51) Int. Cl. H01L 25/065; H01L 23/00; H01L 23/31; H01L 23/498

(52) U.S. Cl. CPC H01L 25/0655; H01L 23/3128; H01L 23/49816; H01L 23/49822; H01L 24/08; H01L 24/16; H01L 2224/08146; H01L 2224/08225; H01L 2224/16146; H01L 2224/16225; H01L 2924/01029; H01L 2924/0695; H01L 2924/15311; H01L 2924/182

(57) ABSTRACT

An electronic package and a manufacturing method thereof are provided, in which an electronic module including a carrier structure, at least one first electronic element disposed on a first side of the carrier structure, at least one second electronic element disposed on a second side of the carrier structure, and a plurality of conductive elements is stacked on a substrate via the plurality of conductive elements and a substrate frame, so as to increase an accommodation space between the electronic module and the substrate, thereby preventing the at least one second electronic element of the electronic module from colliding with the substrate.

### CROSS-REFERENCE TO RELATED APPLICATIONS

The present application is based upon and claims the right of priority to TW Patent application Ser. No. 11/214,1376, filed Oct. 27, 2023, the disclosure of which is hereby incorporated by reference herein in its entirety for all purposes.

### BACKGROUND

### 1. Technical Field

The present disclosure relates to a semiconductor packaging process, and more particularly, to an electronic package integrating multiple chips and a manufacturing method thereof.

### 2. Description of Related Art

With the evolution of semiconductor packaging technology, different

packaging types have been developed for semiconductor devices. In order to improve electrical functions and save packaging space, different three-dimensional packaging technologies have been developed. For example, fan-out package-on-package (FO PoP) is used to cope with the greatly increased number of input/output ports on various chips, thereby integrating integrated circuits with different functions into a single package structure. This packaging method can take advantage of the heterogeneous integration characteristics of system-in-package (SiP), and can integrate electronic elements with different functions, such as: memory, central processing unit, graphics processor, imaging application processor, etc., via stacking design to achieve system integration, and is suitable for use in various thin and light electronic products.

FIG. 1 is a schematic cross-sectional view of a conventional semiconductor package 1. As shown in FIG. 1, the semiconductor package 1 includes a package substrate 10 and a semiconductor module disposed on the package substrate 10 via solder balls 13. Specifically, the semiconductor module includes a circuit structure 15, a first semiconductor chip 11 disposed on the upper side of the circuit structure 15, an encapsulation layer 14 covering the first semiconductor chip 11, and a second semiconductor chip 12 disposed on the lower side of the circuit structure 15.

However, in the conventional semiconductor package 1, the package substrate 10 supports the semiconductor module with only the solder balls 13, so that the second semiconductor chip 12 is likely to collide with the package substrate 10 during assembly, causing damage to the second semiconductor chip 12. Therefore, the thickness of the second semiconductor chip 12 cannot be too large, so that the design of the second semiconductor chip 12 is restricted or the manufacturing difficulty of the second semiconductor chip 12 is too high. As a result, the second semiconductor chip 12 with various specifications cannot be configured according to the optimal placement position of the electronic element in the conventional semiconductor package 1, thereby resulting in unfavorable flexibility in product design.

Furthermore, if the conventional semiconductor package 1 requires more functions when only a small-sized second semiconductor chip 12 can be selected, it is necessary to configure multiple layers of the circuit structures 15 and functional chips 17 on the encapsulation layers 14, and the functional chips 17 are covered by the encapsulation layers 14, wherein a plurality of conductive pillars 16 electrically connected to each of the circuit structures 15 need to be formed in the encapsulation layers 14 so as to transmit signals between the chips. Therefore, not only the manufacturing process is complicated and the manufacturing cost is greatly increased, but also the thickness of the semiconductor package 1 is increased due to the need to stack multiple layers of the functional chips 17, thereby making the semiconductor package 1 difficult to meet the thinning requirements.

Therefore, how to overcome the various problems of the above-mentioned prior art has become an urgent issue to be solved.

### SUMMARY

In view of the various deficiencies of the prior art, the present disclosure provides an electronic package, which comprises: a carrier structure having a first side and a second side opposing the first side; at least one first electronic element bonded onto and electrically connected to the first side of the carrier structure; at least one second electronic element bonded onto and electrically connected to the second side of the carrier structure; a plurality of conductive elements bonded and electrically connected to the second side of the carrier structure; and a substrate frame bonded and electrically connected to the plurality of conductive elements, wherein a space corresponding to a position and quantity of the second electronic element is flexibly provided for accommodating the second electronic element.

The present disclosure also provides a method of manufacturing an electronic package, the method comprises: providing a carrier structure having a first side and a second side opposing the first side, wherein the first side is disposed with at least one first electronic element thereon; disposing at least one second electronic element on the second side of the carrier structure, wherein the at least one second electronic element is electrically connected to the carrier structure; forming a plurality of conductive elements on the second side of the carrier structure, wherein the plurality of conductive elements are electrically connected to the carrier structure to form an electronic module; and bonding the electronic module to a substrate frame, wherein the substrate frame is electrically connected to the plurality of conductive elements, wherein the substrate frame is flexibly provided with a space corresponding to a position and quantity of the second electronic element for accommodating the second electronic element.

In the aforementioned electronic package and method, the at least one first electronic element has an active surface facing the carrier structure and electrically connected to the carrier structure, and the at least one second electronic element has an active surface facing the carrier structure and electrically connected to the carrier structure, so that the active surface of the at least one first electronic element and the active surface of the at least one second electronic element are arranged facing each other.

In the aforementioned electronic package and method, the substrate frame has a circuit structure.

In the aforementioned electronic package and method, the present disclosure further comprises connecting the substrate frame and a substrate. For example, the electronic module is first bonded to the substrate frame and then connected to the substrate; alternatively, the substrate frame is first connected to the substrate, and then the electronic module is bonded to the substrate frame.

In the aforementioned electronic package and method, the present disclosure further comprises covering the substrate frame, the plurality of conductive elements and the at least one second electronic element with a cladding layer.

In the aforementioned electronic package and method, the present disclosure further comprises forming an encapsulation layer on the first side of the carrier structure to cover the at least one first electronic element.

As can be seen from the above, the electronic package and the manufacturing method thereof of the present disclosure rely on the design of the substrate frame to raise the height position of the carrier structure relative to the first surface of the substrate after the substrate frame is bonded to the conductive elements, so that a sufficiently high accommodation space is formed between the carrier structure and the substrate to prevent the second electronic elements from colliding with the first surface of the substrate. Therefore, compared with the prior art, the present disclosure can flexibly design a space for accommodating the second electronic elements in the substrate frame according to the number and placement position of the second electronic elements, thereby facilitating the flexibility of product design.

Furthermore, the manufacturing method of the present disclosure can be implemented using existing semiconductor packaging processes, so there is no need to develop a special manufacturing process or purchase equipment with special specifications. Therefore, compared with the prior art, the manufacturing method of the present disclosure can effectively reduce the production cost of the electronic package.

In addition, the manufacturing method of the present disclosure can configure the multi-functional and large-sized second electronic elements as required, so there is no need to stack conventional functional chips and related configurations on the encapsulation layer. Therefore, compared with the prior art, the manufacturing method of the present disclosure not only simplifies the manufacturing process and greatly reduces the manufacturing cost, but also effectively reduces the thickness of the electronic package to meet the thinning requirements.

### BRIEF DESCRIPTION OF THE DRAWINGS

FIG. 1 is a schematic cross-sectional view of a conventional semiconductor package.

FIG. 2A, FIG. 2B, FIG. 2C-1, FIG. 2D-1 and FIG. 2E are schematic cross-sectional views illustrating a manufacturing method of an electronic package according to the present disclosure.

FIG. 2C-2 is a schematic cross-sectional view of another embodiment of FIG. 2C-1.

FIG. 2D-2 is a schematic partial bottom view of FIG. 2D-1.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

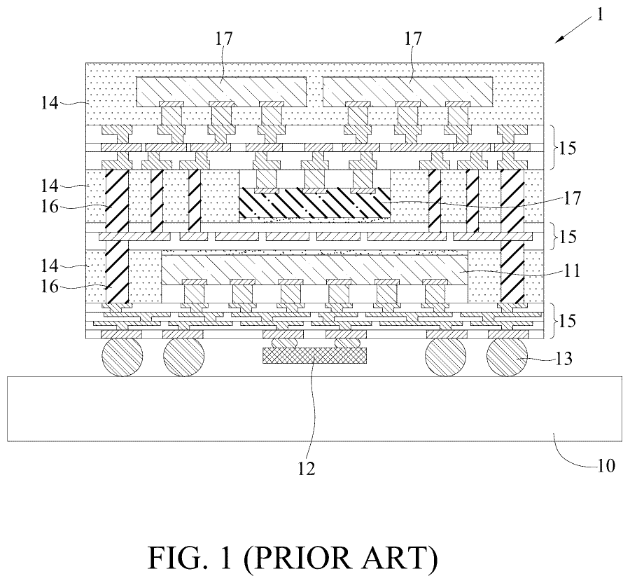

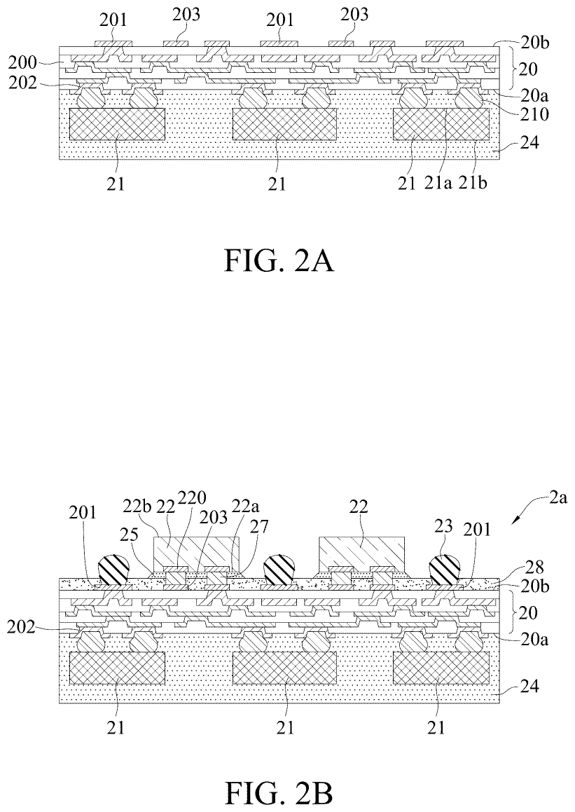

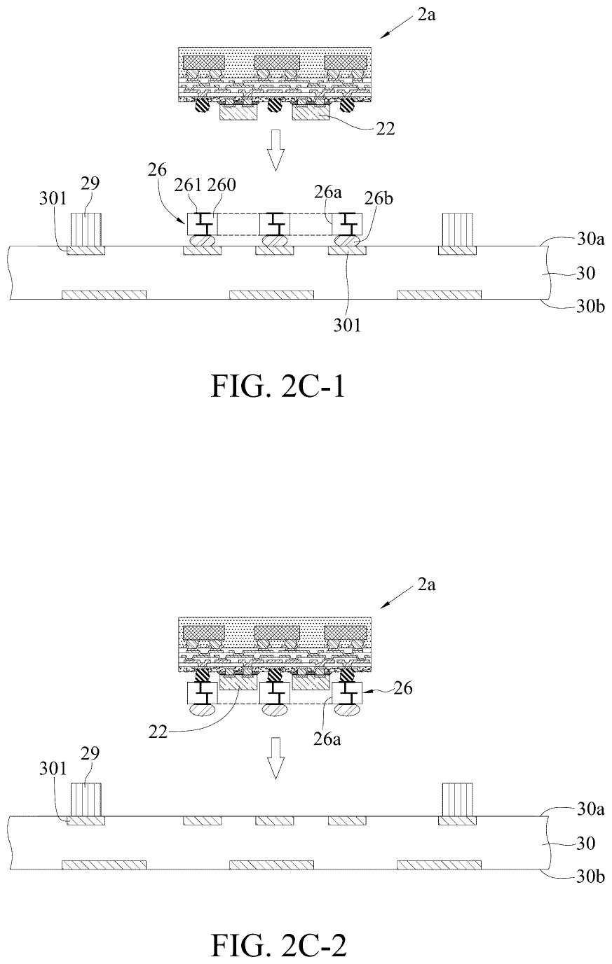

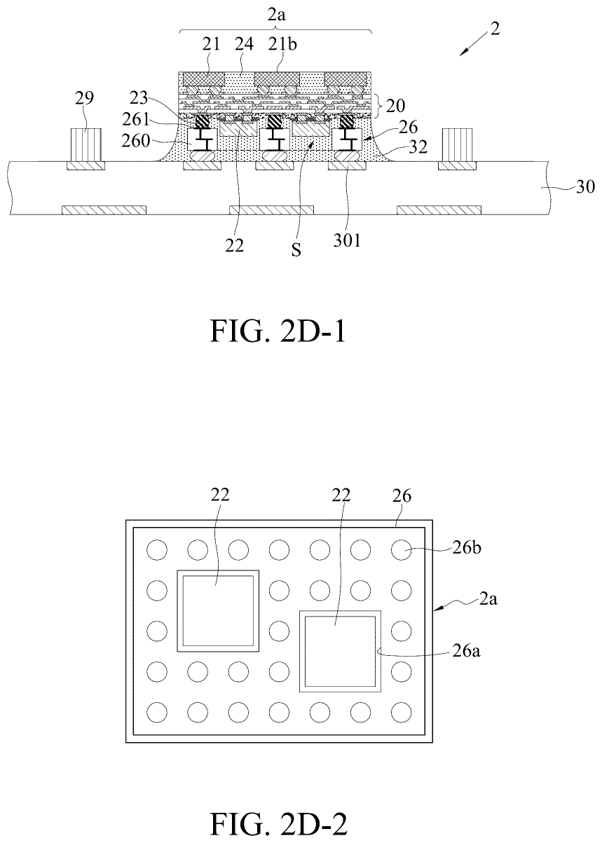

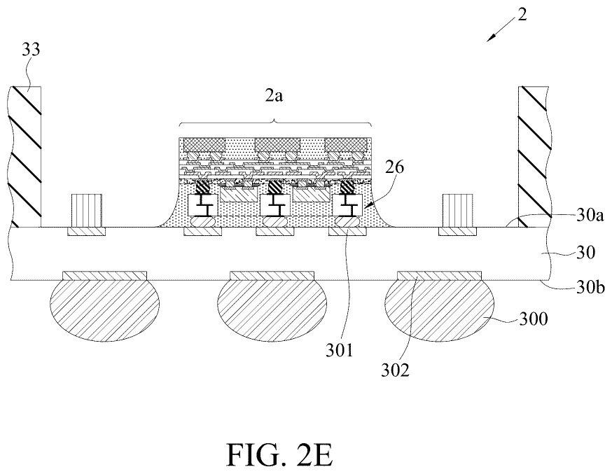

FIG. 2A, FIG. 2B, FIG. 2C-1, FIG. 2D-1 and FIG. 2E are schematic cross-sectional views illustrating a manufacturing method of an electronic package 2 according to the present disclosure.

As shown in FIG. 2A, a carrier structure 20 is provided and is bonded to at least one first electronic element 21 and an encapsulation layer 24. In this embodiment, three first electronic elements 21 are shown.

The carrier structure 20 is, for example, a package substrate having a core layer and a circuit structure, a package substrate having a coreless circuit structure, a through-silicon interposer (TSI) having through-silicon vias (TSVs), or other board types. It should be understood that the carrier structure 20 can also be other types of chip-carrying board, such as a wafer, or other types of board having metal routings, and the like, and the present disclosure is not limited to as such.

In one embodiment, the carrier structure 20 is a coreless package substrate formed by a redistribution layer (RDL) manufacturing method, wherein the carrier structure 20 has a first side 20a and a second side 20b opposing the first side 20a, and the carrier structure 20 includes at least one first dielectric layer 200 and first circuit layers 201, 202, 203 bonded to the first dielectric layer 200. For example, the carrier structure 20 is made of redistribution layers, wherein the first circuit layers 201, 202, 203 are made of copper, and the first dielectric layer 200 is made of a material such as polybenzoxazole (PBO), polyimide (PI), prepreg (PP), or other dielectric materials.

The first electronic elements 21 are bonded onto the first side 20a of the carrier structure 20, wherein each of the first electronic elements 21 is an active element, a passive element, or a combination of the active element and the passive element, wherein the active element is, for example, a semiconductor chip, and the passive element is, for example, a resistor, a capacitor, or an inductor.

In one embodiment, the first electronic elements 21 are semiconductor chips, and each of the first electronic elements 21 has an active surface 21a and an inactive surface 21b opposing the active surface 21a, wherein the active surface 21a is electrically connected to the first circuit layer 202 in a flip-chip manner (via conductive bumps 210 as shown in FIG. 2A); alternatively, the first electronic elements 21 can also be electrically connected to the first circuit layer 202 in a wire-bonding manner via a plurality of bonding wires (not shown); alternatively, the first electronic elements 21 can be directly and electrically connected to the first circuit layer 202. However, the methods for electrically connecting the first electronic elements 21 to the first circuit layer 202 are not limited to the above.

The encapsulation layer 24 is formed on the first side 20a of the carrier structure 20 to cover the first electronic elements 21.

In one embodiment, the encapsulation layer 24 is made of insulating material, such as polyimide (PI), dry film, or epoxy resin encapsulant, and the encapsulation layer 24 can be formed on the first side 20a of the carrier structure 20 by lamination or molding.

As shown in FIG. 2B, a protective layer 28 is formed on the second side 20b of the carrier structure 20, and at least one second electronic element 22 is disposed on the second side 20b of the carrier structure 20 (in this embodiment, two second electronic elements 22 are shown), wherein conductive elements 23 are formed on the second side 20b of the carrier structure 20 to form an electronic module 2a, wherein the height of the conductive element 23 relative to the second side 20b is less than the height of the second electronic element 22 relative to the second side 20b.

The protective layer 28 is for example a solder-resist layer (such as a solder mask) made of insulating material, and the protective layer 28 is formed with a plurality of openings, so that the first circuit layers 201, 203 are exposed from the openings.

Each of the second electronic elements 22 is an active element, a passive element, or a combination of the active element and the passive element, wherein the active element is, for example, a semiconductor chip, and the passive element is, for example, a resistor, a capacitor, or an inductor.

In one embodiment, the second electronic elements 22 are semiconductor chips, and each of the second electronic elements 22 has an active surface 22a and an inactive surface 22b opposing the active surface 22a, wherein the active surface 22a has a plurality of electrode pads 220, so that the electrode pads 220 of the second electronic elements 22 are electrically connected to the first circuit layer 203 in a flip-chip manner via a plurality of conductive bumps 27, and then the conductive bumps 27 are covered with an insulating layer 25 such as an underfill; alternatively, the second electronic elements 22 can also be electrically connected to the first circuit layer 203 in a wire-bonding manner via a plurality of bonding wires (not shown); alternatively, the second electronic elements 22 can be directly and electrically connected to the first circuit layer 203. However, the methods for electrically connecting the second electronic elements 22 to the first circuit layer 203 are not limited to the above.

Furthermore, the active surface 21a of each of the first electronic elements 21 and the active surface 22a of each of the second electronic elements 22 are arranged face to face.

The conductive elements 23 are made of solder material or are metal pillars such as copper pillars, and the conductive elements 23 are electrically connected to the first circuit layer 201.

As shown in FIG. 2C-1, a substrate 30 is provided and has a first surface 30a and a second surface 30b opposing the first surface 30a, and at least one substrate frame 26 and at least one auxiliary electronic element 29 are disposed on the first surface 30a, wherein the substrate frame 26 has openings 26a for accommodating the second electronic elements 22. Next, as shown in FIG. 2D-1, the conductive elements 23 of the electronic module 2a are bonded to the substrate frame 26 to form the electronic package 2. In an embodiment, the electronic module 2a can be connected to a substrate surface of the substrate frame 26 and the substrate 30 (the substrate frame 26 and the substrate 30 have been connected in advance). In another embodiment, as shown in FIG. 2C-2, the electronic module 2a can be first bonded with the substrate frame 26, and then the electronic module 2a and the substrate frame 26 are connected onto the substrate 30, wherein the substrate frame 26 has the openings 26a for accommodating the second electronic elements 22.

Please refer to FIG. 2D-2. The substrate frame 26 can be provided with the openings 26a corresponding to the number and position of the second electronic elements 22 in the electronic module 2a as required. That is to say, the present disclosure can flexibly design spaces (the openings 26a) for accommodating the second electronic elements 22 in the substrate frame 26 according to the number and arrangement position of the second electronic elements 22.

In one embodiment, the substrate frame 26 has a circuit structure and comprises at least one second dielectric layer 260 and at least one second circuit layer 261 (such as of RDL specification) formed on the second dielectric layer 260 and electrically connected to the substrate 30, wherein the outermost second circuit layer 261 is exposed from the second dielectric layer 260, is electrically connected to the electronic module 2a via the conductive elements 23, and is electrically connected to the substrate 30 via conductive elements 26b. For example, the material for forming the second circuit layer 261 is copper, and the material for forming the second dielectric layer 260 is a dielectric material such as polybenzoxazole (PBO), polyimide (PI), or prepreg (PP).

Furthermore, the auxiliary electronic element 29 is a passive element such as a resistor, a capacitor, or an inductor, and the first surface 30a of the substrate 30 has a plurality of electrical contact pads 301, so that the second circuit layer 261 and the auxiliary electronic element 29 are electrically connected to the electrical contact pads 301.

In addition, according to requirements, the outer surface of the encapsulation layer 24 of the electronic module 2a can be flush with the inactive surface 21b of each of the first electronic elements 21 via a leveling process, such as grinding, so that the inactive surface 21b of each of the first electronic elements 21 is exposed from the encapsulation layer 24.

In addition, the substrate frame 26, the conductive elements 23, 26b and the second electronic elements 22 can be covered by a cladding layer 32 such as an underfill.

As shown in FIG. 2E, a ball placement process is performed on ball placement pads 302 on the second surface 30b of the substrate 30 to form a plurality of solder balls 300. Therefore, in the subsequent manufacturing process, the electronic package 2 is disposed on a circuit board (not shown) via the solder balls 300.

In one embodiment, a strengthening member 33, such as a metal frame, can be disposed on the substrate 30 as required to solve the problem of stress concentration, prevent the substrate 30 from warping and provide a heat dissipation function.

Therefore, the manufacturing method of the present disclosure mainly relies on the design of the substrate frame 26 to increase the height of the carrier structure 20 relative to the first surface 30a of the substrate 30 when the substrate frame 26 is bonded to the conductive elements 23, so that a sufficiently high accommodation space S is formed between the carrier structure 20 and the substrate 30 to prevent the second electronic elements 22 from colliding with the first surface 30a of the substrate 30.

Therefore, compared with the prior art, the electronic package 2 of the present disclosure can be configured with the second electronic elements 22 of various specifications according to the placement requirements of the electronic elements without having to consider the height dimensions of the second electronic elements 22 or the conductive elements 23, thereby facilitating the flexibility of product design.

Furthermore, the manufacturing method of the present disclosure can be implemented using the existing semiconductor packaging process, so there is no need to develop a special process or purchase equipment with special specifications. Therefore, the manufacturing method of the present disclosure can effectively reduce the production cost of the electronic package 2.

In addition, the manufacturing method of the present disclosure can configure the multi-functional and large-sized second electronic elements 22 as required, so there is no need to stack conventional functional chips and related configurations on the encapsulation layer 24. At the same time, since the active surfaces 21a of the first electronic elements 21 and the active surfaces 22a of the second electronic elements 22 are arranged facing each other, these electronic elements can communicate vertically to meet high-speed transmission requirements and obtain optimal electrical performance. Therefore, compared with the prior art, the manufacturing method of the present disclosure not only simplifies the manufacturing process and greatly reduces the manufacturing cost, but also effectively reduces the thickness of the electronic package 2 to meet the thinning requirements.

The present disclosure provides an electronic package 2, which comprises: a carrier structure 20, at least one first electronic element 21, an encapsulation layer 24, at least one second electronic element 22, a plurality of conductive elements 23 and a substrate frame 26.

The carrier structure 20 has a first side 20a and a second side 20b opposing the first side 20a.

The first electronic element 21 is bonded onto and electrically connected to the first side 20a of the carrier structure 20.

The encapsulation layer 24 is formed on the first side 20a of the carrier structure 20 and covering the first electronic element 21.

The second electronic element 22 is bonded onto and electrically connected to the second side 20b of the carrier structure 20.

The conductive elements 23 are bonded onto and electrically connected to the second side 20b of the carrier structure 20.

The substrate frame 26 is bonded to and electrically connected to the conductive elements 23 and does not cover the second electronic element 22.

In one embodiment, the first electronic element 21 has an active surface 21a facing the carrier structure 20 and electrically connected to the carrier structure 20, and the second electronic element 22 has an active surface 22a facing the carrier structure 20 and electrically connected to the carrier structure 20, so that the active surface 21a of the first electronic element 21 and the active surface 22a of the second electronic element 22 are arranged facing each other.

In one embodiment, the substrate frame 26 has a circuit structure.

In one embodiment, the electronic package 2 further comprises a substrate 30 connected to the substrate frame 26.

For example, in one embodiment, the electronic package 2 further comprises a cladding layer 32 covering the substrate frame 26, the conductive elements 23 and the second electronic element 22.

To sum up, the electronic package and the manufacturing method thereof of the present disclosure rely on the design of the substrate frame to raise the height position of the carrier structure relative to the first surface of the substrate, so that a sufficiently high accommodation space is formed between the carrier structure and the substrate to prevent the second electronic elements from colliding with the first surface of the substrate. At the same time, the present disclosure can flexibly design a space for accommodating the second electronic elements in the substrate frame according to the number and placement position of the second electronic elements. Therefore, the electronic package of the present disclosure can be configured with the second electronic elements of various specifications according to the placement requirements of the electronic elements, thereby facilitating the flexibility of product design.

Furthermore, the manufacturing method of the present disclosure can be implemented using existing semiconductor packaging processes, so there is no need to develop a special manufacturing process or purchase equipment with special specifications. Therefore, the manufacturing method of the present disclosure can effectively reduce the production cost of the electronic package.

In addition, the manufacturing method of the present disclosure can configure the multi-functional and large-sized second electronic elements as required, so there is no need to stack conventional functional chips and related configurations on the encapsulation layer. Therefore, the manufacturing method of the present disclosure not only simplifies the manufacturing process and greatly reduces the manufacturing cost, but also effectively reduces the thickness of the electronic package to meet the thinning requirements.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first side and a second side opposing the first side;
at least one first electronic element bonded onto and electrically connected to the first side of the carrier structure;
at least one second electronic element bonded onto and electrically connected to the second side of the carrier structure;
a plurality of conductive elements bonded and electrically connected to the second side of the carrier structure; and
a substrate frame bonded and electrically connected to the plurality of conductive elements, wherein a space corresponding to a position and quantity of the second electronic element is flexibly provided for accommodating the second electronic element.

2. The electronic package of claim 1, wherein the at least one first electronic element has an active surface facing the carrier structure and electrically connected to the carrier structure, and the at least one second electronic element has an active surface facing the carrier structure and electrically connected to the carrier structure, so that the active surface of the at least one first electronic element and the active surface of the at least one second electronic element are arranged facing each other.

3. The electronic package of claim 1, wherein the substrate frame has a circuit structure.

4. The electronic package of claim 1, further comprising a substrate connected to the substrate frame.

5. The electronic package of claim 1, further comprising a cladding layer covering the substrate frame, the plurality of conductive elements and the at least one second electronic element.

6. The electronic package of claim 1, further comprising an encapsulation layer formed on the first side of the carrier structure and covering the at least one first electronic element.

7. A method of manufacturing an electronic package, comprising:
providing a carrier structure having a first side and a second side opposing the first side, wherein the first side is disposed with at least one first electronic element thereon;
disposing at least one second electronic element on the second side of the carrier structure, wherein the at least one second electronic element is electrically connected to the carrier structure;
forming a plurality of conductive elements on the second side of the carrier structure, wherein the plurality of conductive elements are electrically connected to the carrier structure to form an electronic module; and
bonding the electronic module to a substrate frame, wherein the substrate frame is electrically connected to the plurality of conductive elements, wherein the substrate frame is flexibly provided with a space corresponding to a position and quantity of the second electronic element for accommodating the second electronic element.

8. The method of claim 7, wherein the at least one first electronic element has an active surface facing the carrier structure and electrically connected to the carrier structure, and the at least one second electronic element has an active surface facing the carrier structure and electrically connected to the carrier structure, so that the active surface of the at least one first electronic element and the active surface of the at least one second electronic element are arranged facing each other.

9. The method of claim 7, wherein the substrate frame has a circuit structure.

10. The method of claim 7, further comprising connecting the substrate frame and a substrate.

11. The method of claim 10, wherein the electronic module is first bonded to the substrate frame and then connected to the substrate.

12. The method of claim 10, wherein the substrate frame is first connected to the substrate, and then the electronic module is bonded to the substrate frame.

13. The method of claim 7, further comprising covering the substrate frame, the 5 plurality of conductive elements and the at least one second electronic element with a cladding layer.

14. The method of claim 7, further comprising forming an encapsulation layer on the first side of the carrier structure to cover the at least one first electronic element.
